(19) United States
(12) Patent Application Publication
(10) Pub. No.: US 2024/0288981 A1
(43) Pub. Date: Aug. 29, 2024

(54) DISPLAY DEVICE

(71) Applicant: Samsung Display Co., Ltd., Yongin-si, Gyeonggi-do (KR)

(72) Inventors: SUNG-KI JUNG, Yongin-si, Gyeonggi-do (KR); Minjee KIM, Yongin-si, Gyeonggi-do (KR)

(73) Assignee: Samsung Display Co., Ltd., Yongin-si, Gyeonggi-do (KR)

(21) Appl. No.: 18/545,018

(22) Filed: Dec. 19, 2023

(30) Foreign Application Priority Data
Feb. 27, 2023 (KR) 10-2023-0025665

(51) Int. Cl. G06F 3/046; G06F 3/041

(52) U.S. Cl. CPC G06F 3/046; G06F 3/0412; G06F 2203/04102; G06F 2203/04107

(57) ABSTRACT

Provided is a display device including a display module, a support plate disposed below the display module, and a digitizer module, the digitizer module includes a digitizer layer including a base layer, a first coil disposed on a top surface of the base layer, and a second coil disposed on a bottom surface of the base layer, a shield layer disposed below the digitizer layer, and including a magnetic metal powder, and a prepreg layer disposed below the digitizer layer and over or below the shield layer.

### CROSS-REFERENCE TO RELATED APPLICATIONS

This application claims priority to and benefits of Korean Patent Application No. 10-2023-0025665 under 35 U.S.C. § 119, filed on Feb. 27, 2023, the entire contents of which are incorporated herein by reference.

### BACKGROUND

### 1. Technical Field

The disclosure herein relates to a display device, and a display device including a digitizer module.

### 2. Description of the Related Art

A display device displays various images on a display screen to provide information to a user. A display device displays information in an allocated screen. Recently, flexible display devices including a foldable flexible display device are being developed. Unlike a rigid display device, the flexible display device is foldable, rollable, or bendable. The flexible display device may be variously modified in shape to be carried regardless of a screen size, thereby improving the user convenience.

The display device may include a digitizer module including various sensing coils so as to be activated by an electrical signal, and a metal support layer or the like may be used in the flexible display device to secure the rigidity of the digitizer module. However, in case that the metal support layer is used, the surface quality of the digitizer module is lowered and the entire weight of the display device increases.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a display device including a lightweight digitizer module.

The disclosure also provides a display device including a digitizer module with excellent rigidity and surface quality.

An embodiment provides a display device that may include a display module comprising a folding display part; a first non-folding display part; and a second non-folding display part with the folding display part disposed between the first non-folding display part and the second non-folding display part; a support plate disposed below the display module, and comprising a plurality of openings that overlap the folding display part; and a digitizer module comprising a first digitizer module overlapping the first non-folding display part and a second digitizer module overlapping the second non-folding display part, the first digitizer module and the second digitizer module being disposed below the support plate and spaced apart from each other in an area overlapping the folding display part, wherein the digitizer module may include a digitizer layer comprising a base layer; a first coil disposed on a top surface of the base layer; and a second coil disposed on a bottom surface of the base layer; a shield layer disposed below the digitizer layer, and comprising a magnetic metal powder; and a prepreg layer disposed, below the digitizer layer, over or below the shield layer.

In an embodiment, the digitizer module may further include a first cover layer covering the first coil and disposed over the base layer; and a second cover layer covering the second coil and disposed below the base layer.

In an embodiment, the shield layer may be disposed below the second cover layer, and the prepreg layer may be disposed below the shield layer.

In an embodiment, the prepreg layer may be disposed below the second cover layer, and the shield layer may be disposed below the prepreg layer.

In an embodiment, the digitizer module may further include a metal sheet, the shield layer may be disposed below the second cover layer, and the prepreg layer may be disposed below the shield layer, and the metal sheet may be disposed between the shield layer and the prepreg layer.

In an embodiment, the digitizer module may further include a metal sheet disposed below the digitizer layer; and adhesive layers disposed on at least one of a top and bottom of the shield layer, a top and bottom of the prepreg layer, and a top and bottom of the metal sheet.

In an embodiment, the metal sheet may include copper.

In an embodiment, the digitizer module may further include a first cover layer covering the first coil and disposed over the base layer; and the prepreg layer may cover the second coil and be disposed below the base layer, and the shield layer is disposed below the prepreg layer.

In an embodiment, the digitizer layer may include a first digitizer layer comprised in the first digitizer module, and a second digitizer layer comprised in the second digitizer module, the prepreg layer may include a first prepreg layer comprised in the first digitizer module, and a second prepreg module comprised in the second digitizer module, and a first space interval between the first digitizer layer and the second digitizer layer in the first direction may be less than a second space interval between the first prepreg layer and the second prepreg layer in the first direction.

In an embodiment, the first prepreg layer and the second prepreg layer may not overlap the folding display part.

In an embodiment, at least a portion of the first digitizer layer and at least a portion of the second digitizer layer each may overlap the folding display part.

In an embodiment, the prepreg layer may include glass fibers or carbon fibers.

In an embodiment, a thickness of the prepreg layer may be in a range of about 50 μm to about 60 μm.

In an embodiment, a display device may include
a display module; a support plate disposed below the display module; and a digitizer module disposed below the support plate, wherein the digitizer module further may include a digitizer layer comprising a base layer; a first coil disposed on a top surface of the base layer; and a second coil disposed on a bottom surface of the base layer; a shield layer disposed below the digitizer layer, and comprising a magnetic metal powder; and a prepreg layer disposed, below the digitizer layer, over and below the shield layer, and comprising glass fibers or carbon fibers.

In an embodiment, the digitizer module may further include a first cover layer covering the first coil and disposed over the base layer; and a second cover layer covering the second coil and disposed in a lower portion of the base layer.

In an embodiment, the first cover layer and the second cover layer each may include a sensing adhesive layer covering the first coil or the second coil; and an insulation layer spaced apart from the base layer with the sensing adhesive layer interposed between the insulation layer and the base layer.

In an embodiment, the shield layer may be disposed below the second cover layer, and the prepreg layer may be disposed below the shield layer.

In an embodiment, the prepreg layer may be disposed below the second cover layer, and the shield layer may be disposed below the prepreg layer.

In an embodiment, the digitizer module may further include a metal sheet, the shield layer may be disposed below the second cover layer, and the prepreg layer may be disposed below the shield layer, wherein the metal sheet is disposed between the shield layer and the prepreg layer.

In an embodiment, the digitizer module may further include a first cover layer covering the first coil and disposed over the base layer, the prepreg layer may cover the second coil and be disposed below the base layer, and the shield layer may be disposed below the prepreg layer.

### BRIEF DESCRIPTION OF THE DRAWINGS

The accompanying drawings are included to provide a further understanding of the disclosure, and are incorporated in and constitute a part of this specification. The drawings illustrate embodiments and, together with the description, serve to explain principles of the disclosure. In the drawings:

FIG. 1A is a schematic perspective view showing an unfolded state of a display device according to an embodiment;

FIG. 1B is a schematic perspective view showing a folding operation of a display device according to an embodiment;

FIG. 1C is a schematic plan view showing a folded state of a display device according to an embodiment;

FIG. 1D is a schematic perspective view showing a folding operation of a display device according to an embodiment;

FIG. 2 is a block diagram of a display device according to an embodiment;

FIG. 3 is an exploded perspective view of a display device according to an embodiment;

FIG. 4 is a schematic cross-sectional view of a display device according to an embodiment;

FIG. 5 is a schematic cross-sectional view of a digitizer module according to an embodiment;

FIG. 6A is a schematic plan view of a digitizer layer according to an embodiment;

FIG. 6B is a schematic plan view of a digitizer layer according to an embodiment;

FIG. 7A is a schematic perspective view of a prepreg layer according to an embodiment;

FIG. 7B is a schematic cross-sectional view of a prepreg layer according to an embodiment;

FIG. 8 is a schematic cross-sectional view of a typical digitizer module;

FIG. 9 is a schematic cross-sectional view of a digitizer module according to an embodiment;

FIG. 10 is a schematic cross-sectional view of a digitizer module according to an embodiment; and

FIG. 11 is a schematic cross-sectional view of a digitizer module according to an embodiment.

### DETAILED DESCRIPTION OF THE EMBODIMENTS

The disclosure may be variously modified and realized in various forms, and thus embodiments will be illustrated in the drawings and described in detail hereinafter. However, it will be understood that the disclosure is not intended to be limited to the forms set forth herein, and all changes, equivalents, and substitutions included in the technical scope and spirit of the disclosure are included.

It will be understood that when an element or layer is referred to as being “on”, “connected to” or “coupled to” another element or layer, it can be directly on, connected or coupled to the other element or intervening third elements may be present.

“Being directly disposed” may mean that there is not an additional layer, film, area, plate or the like between a portion of a layer, film, area, plate or the like, and another portion. For example, “being directly disposed” may mean that disposition of two layers or two members is performed without an additional member such as an adhesive member therebetween.

Like reference numerals in the drawings refer to like elements. In the drawings, the thickness, ratio and dimension of the element are exaggerated for effective description of the technical contents.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Terms such as first, second, and the like may be used to describe various components, but these components should not be limited by the terms. These terms are only used to distinguish one element from another. For instance, a first component may be referred to as a second component, or similarly, a second component may be referred to as a first component, without departing from the scope of the disclosure.

As used herein, the singular forms, “a,” “an,” and “the” are intended to include the plural forms as well, unless the context clearly indicates otherwise.

The terms such as “under”, “lower”, “on”, and “upper” are used for explaining associations of items illustrated in the drawings. The terms are used as a relative concept and are described with reference to the direction indicated in the drawings. In the specification, the term “disposed on” may refer to not only an upper portion of any member but also a lower portion thereof.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by one of ordinary skill in the art to which the disclosure pertains. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

It will be further understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Hereinafter, a display device according to an embodiment will be described with reference to the drawings.

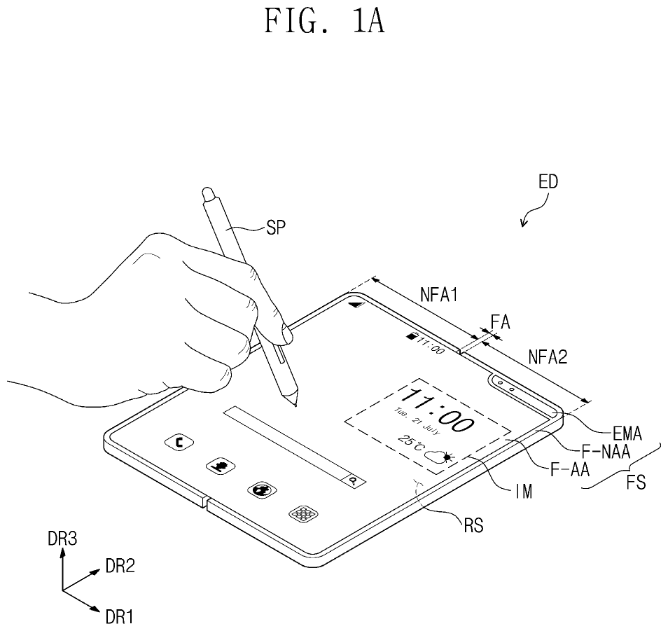

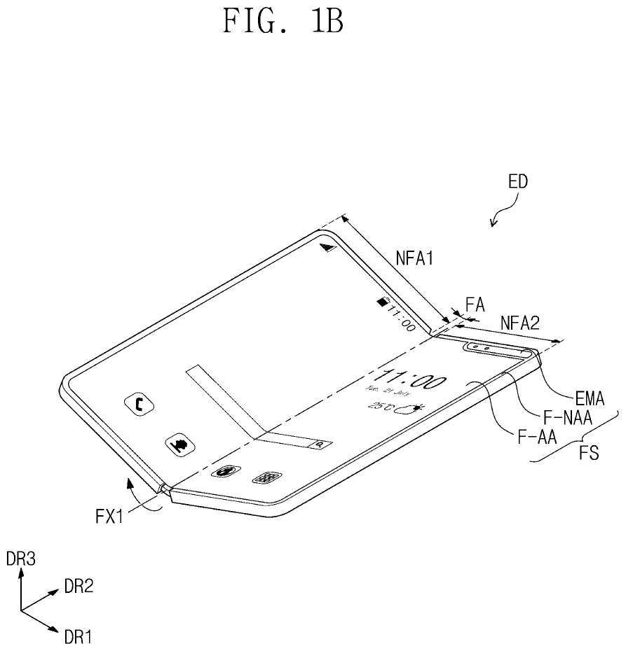

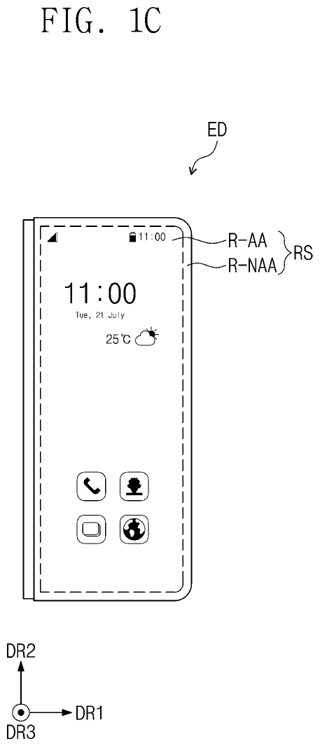

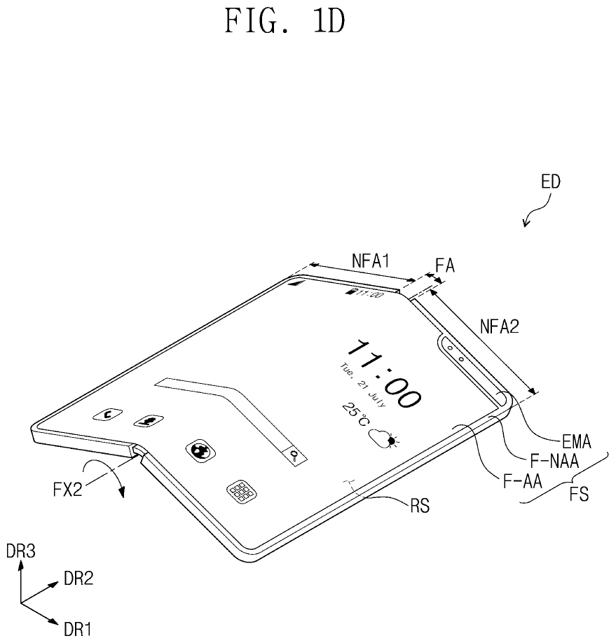

FIG. 1A is a schematic perspective view showing an unfolded state of a display device ED according to an embodiment. The display device ED according to an embodiment may be a device activated according to an electrical signal. For example, the display device ED may be a mobile phone, a tablet computer, a vehicle navigation system, a game device, or a wearable device, but the embodiment thereof is not limited thereto. FIG. 1A or the like disclosed herein shows a mobile phone as the example display device ED.

The display device ED according to the embodiment may include a first display surface FS defined by a first directional axis DR1 and a second directional DR2 that intersects the first directional axis DR1. The display device ED may provide a user an image IM through the first display surface FS. The display device ED according to an embodiment may display an image IM on the display surface FS parallel to the first direction DR1 and the second direction DR2 towards the third direction DR3. In the specification, on the basis of the direction in which the image IM is displayed, the front surface (or the top surface) and the rear surface (or the bottom surface) of each component are defined. The front surface and the rear surface are opposite to each other in a third direction DR3, and normal directions of the front surface and the rear surface may be parallel to the third direction DR3.

FIG. 1A and the other drawings show the first direction DR1 to the third direction DR3, and the directions indicated by the first to third directions DR1, DR2, and DR3 may be relative concepts and converted into other directions. Directional axes indicated by the first to third directions DR1, DR2, and DR3 may be described as the first to third directions, and be referred to as like reference numerals.

The display device ED according to an embodiment may detect an externally applied input. The external input may include various types of inputs provided from the outside of the display device ED. For example, the external input may include an external input (for example, hovering) closely applied to or adjacently applied to the display device ED at a prescribed distance as well as a contact with a part, such as a hand, of the user's body. The user input may be of various types such as force, pressure, temperature, or light, etc.

FIG. 1A shows an example external input through a pen SP. Although not shown, the pen SP may be attached to and detached from the inside or outside of the display device ED, and the display device ED may provide and receive signals corresponding to the attachment and detachment of the pen SP.

The display device ED according to an embodiment may include a first display surface FS and a second display surface RS. The first display surface FS may include a first active area F-AA, a first peripheral area F-NAA, and an electronic module area EMA. The second display surface RS may be defined as a surface opposite to at least a portion of the first display surface FS. In other words, the second display surface RS may be defined as a portion of the rear surface of the display device ED.

The first active area F-AA may be an area activated according to electrical signals. The first active area F-AA may be an area in which the image IM is displayed and the inputs from the pen SP are detected.

The first peripheral area F-NAA may be adjacent to the first active area F-AA. The first peripheral area F-NAA may have a prescribed color. The first peripheral area F-NAA may surround the first active area F-AA. Accordingly, the shape of the first active area F-AA may be substantially defined by the first peripheral area F-NAA. However, this is an example, and the first peripheral area F-NAA may be disposed adjacent only to one side or a side of the active area F-AA or may be omitted.

The electronic module area EMA may have various electronic modules disposed therein. For example, the electronic module may include at least one of a camera, a speaker, a light sensitive sensor, or a thermal sensor. In the electronic module area EMA, an external subject may be detected from images received through the display surfaces FS, RS, or sound signals such as voice may be provided to the outside through the display surfaces FS, RS. The electronic module may also include a plurality of components, and is not limited to any one embodiment.

The electronic module area EMA may be surrounded by the first peripheral area F-NAA. However, this is an example, and the embodiment is not limited to any one embodiment. For example, the electronic module area EMA may be surrounded by the first active area F-AA and the first peripheral area F-NAA, and the electronic module area EMA may be disposed within the first active area F-AA.

The display device ED according to an embodiment may include at least one folding area FA and a plurality of non-folding areas NFA1 and NFA2 extending from the folding area FA. For example, the first non-folding area NFA1, the folding area FA, and the second non-folding area NFA2 may be defined along the first direction DR1. The display device ED according to an embodiment may include the first non-folding area NFA1 and the second non-folding area NFS2 that are spaced apart in the first directional axis DR1 with the folding area FA1 interposed therebetween. For example, the first non-folding area NFA1 may be disposed at one side or a side of the folding area FA along the first direction DR1, and the second non-folding area NFA2 may be disposed at the other side of the folding area FA along the first direction DR1.

FIG. 1A or the like shows an embodiment of the display device ED including one folding area FA1. However, the embodiment is not limited thereto and a plurality of folding areas may be defined in the display device ED. For example, the display device according to an embodiment may include two or more folding areas, or include three or more non-folding areas with each of the folding areas interposed therebetween.

FIG. 1B is a schematic perspective view showing a folding operation of the display device ED according to an embodiment, FIG. 1C is a schematic plan view of a folded state of the display device ED according to an embodiment, and FIG. 1D is a schematic perspective view showing a folding operation of the display device ED according to an embodiment.

Referring to FIG. 1B, the display device ED according to an embodiment may be folded along a first folding axis FX1 extending in the second direction DR2. In the folded state of the display device ED, the folding area FA may have a prescribed curvature and radius of curvature. The display device ED may be folded along the first folding axis FX1 to cause the first non-folding area NFA1 and the second non-folding area NFA2 to face each other, and may be modified to an in-folding state so that the first display surface FS is not exposed to the outside.

Referring to FIG. 1C, in the in-folding state of the display device ED according to an embodiment, a second display surface RS may be visualized by the user. Here, the second display surface RS may include a second active area R-AA. The second active area R-AA may be activated according to electrical signals. The second active area R-AA may be an area in which the image IM is displayed and various types of external inputs are detected.

The second peripheral area R-NAA may be adjacent to the second active area R-AA. The second peripheral area F-NAA may have a prescribed color. The second peripheral area R-NAA may surround the second active area R-AA. Although not shown, the second display surface RS may further include an electronic module area in which an electronic module including various components is disposed, and is not limited to any one embodiment.

Referring to FIG. 1D, the display device ED according to an embodiment may be folded along a second folding axis FX2 extending in the second direction DR2. The display device ED may be modified to an out-folding state so that the first display surface FS is exposed to the outside. In an embodiment, the display device ED may be formed so that the in-folding and out-folding operations are alternately repeated from an unfolding operation, but the embodiment is not limited thereto.

FIGS. 1A to 1D show example cases where the display device ED is folded along one folding axis FX1 or FX2, but the number of folding axes and the number of non-folding areas according thereto are not limited thereto. For example, the display device ED may be folded along a plurality of folding axes, so that respective portions of the first display surface FS and the second display surface RS may be folded to face each other.

In the display device ED of an embodiment, the first non-folding area NFA1 and the second non-folding area NFA2 may be defined as portions having the display surfaces FS, RS that are parallel to a plane defined by the first directional axis DR1 and the second directional axis DR2 in the folded state as shown in FIG. 1C, and the folding area FA may be defined as an area between the first non-folding area NFA1 and the second non-folding area NFA2. The folding area FA may include a curved part bended to have a prescribed curvature in the folded state.

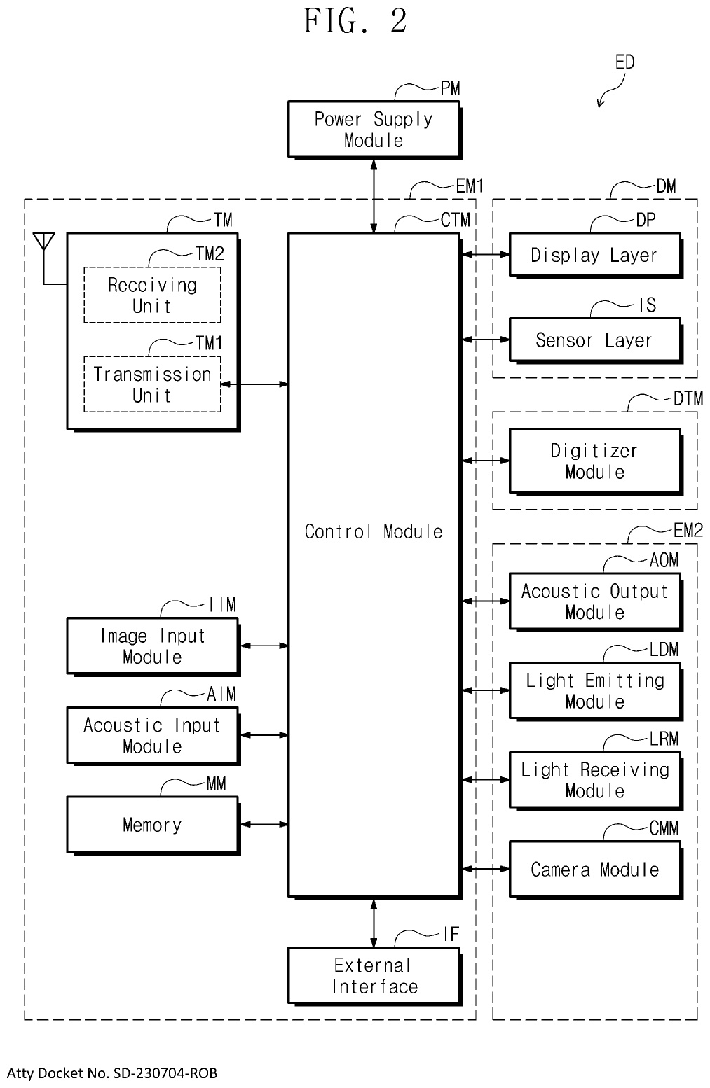

FIG. 2 is a block diagram of the display device ED according to an embodiment. Referring to FIG. 2, the display device ED according to an embodiment may include a display module DM, a digitizer module DTM, a power supply module PM, a first electronic module EM1 and a second electronic module EM2. The display module DM, the digitizer module DTM, the power supply module DM, the first electronic module EM1, and the second electronic module EM2 may be electrically connected to each other.

The display module DM may include a display layer DP and a sensor layer IS. The display layer DP may be a component formed to substantially generate an image. The image generated by the display layer DP may be visualized by a user in the outside through the first display surface FS (see FIG. 1 A).

The first electronic module EM1 and the second electronic module EM2 include various functional modules for operating the display device ED. The first electronic module EM1 may be directly mounted on a mother board that is electrically connected to the display module DM or mounted on a separate board to be electrically connected to the mother board though a connector (not shown).

The first electronic module EM1 may include a control module CTM, a wireless communication module TM, an image input module IIM, an acoustic input module AIM, a memory MM, and an external interface IF. Some or a number of the modules may not be mounted in the mother board, and may be electrically connected to the mother board through a separate flexible circuit board.

The control module CTM controls the overall operation of the electronic device ED. The control module CTM may be a microprocessor. For example, the control module CTM may activate or deactivate the display panel DM. The control module CTM may control the other modules such as the image input module IIM or the acoustic input module AIM on the basis of touch signals received from the display panel DM.

The wireless communication module TM may transmit/receive a wireless signal to/from another terminal using Bluetooth or a Wi-Fi channel. The wireless communication module TM may transmit/receive a voice signal using a general communication line. The wireless communication module TM may include a transmission unit TM1 which modulates a signal to be transmitted and transmits the modulated signal, and a receiving unit TM2 which demodulates a received signal.

The image input module IIM may process an image signal to convert the processed image signal into image data displayable on the display module DM. The acoustic input module AIM may receive an external acoustic signal through a microphone in a recording mode, a voice recognition mode or the like to convert the acoustic signal to electrical voice data.

The external interface IF may serve as an interface connected to an external charger, a wired/wireless data port, a card socket (for example, a memory card, a SIM/UIM card) or the like within the spirit and the scope of the disclosure.

The second electronic module EM2 may include an acoustic output module AOM, a light emitting module LDM, a light receiving module LRM and a camera module CMM, etc. The components may be directly mounted in the mother board, or mounted in a separate board to be electrically connected to the display module DM through a connector (not shown), etc., or electrically connected to the first electronic module EM1.

The acoustic output module AOM may convert, into voices, acoustic data received from the wireless communication module TM or acoustic data stored in the memory MM, and outputs the voices to the outside.

The light emitting module LDM may generate and output light. For example, the light emitting module LDM may output infrared light. The light emitting module LDM may include LED elements. The light receiving module LRM may sense infrared light. The light receiving module LRM may be activated in case that sensing the infrared light of a prescribed level or higher. The light receiving module LRM may include CMOS sensors. After the infrared light generated by the light emitting module LDM is output, the infrared light is reflected by an external object (for example, a finger or the face of the user), and incident to the light receiving module LRM. The camera module CMM may capture an external image.

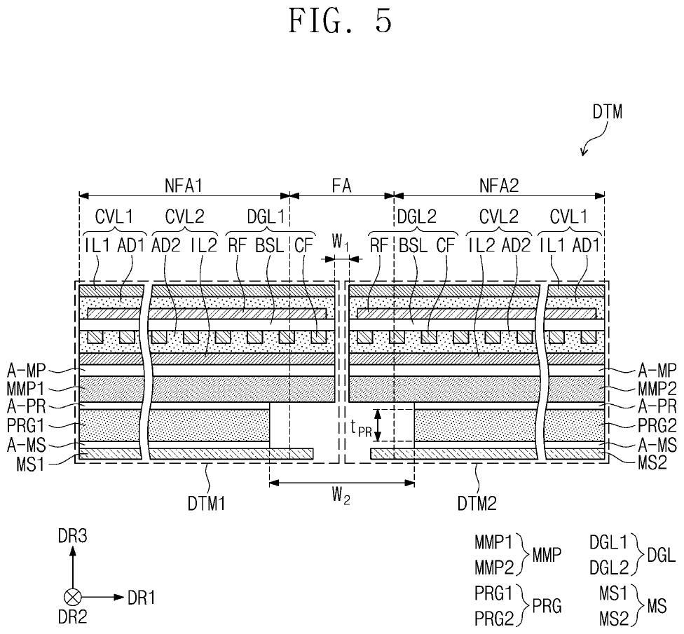

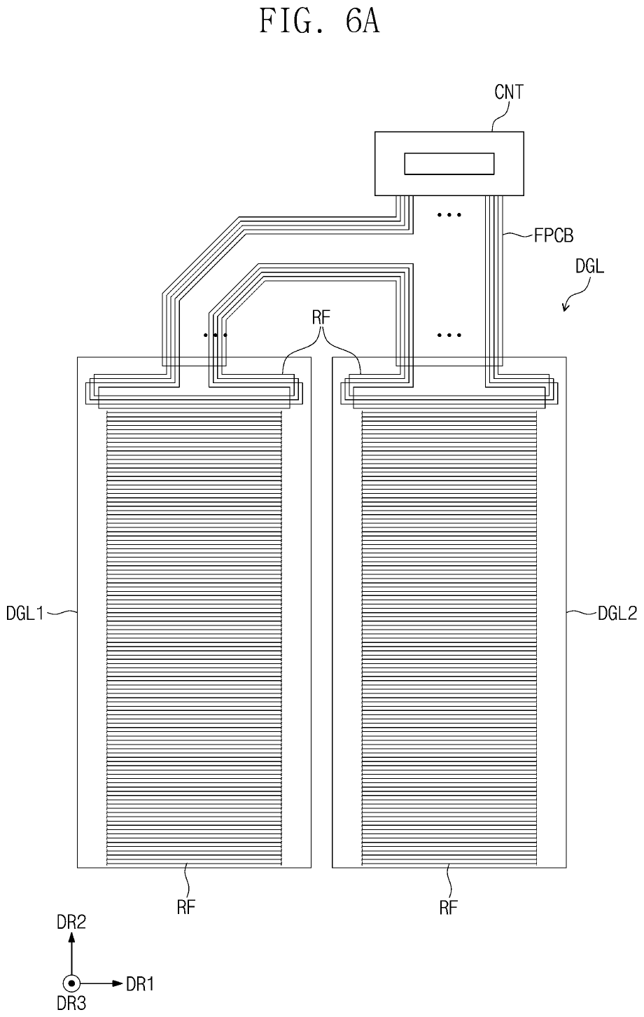

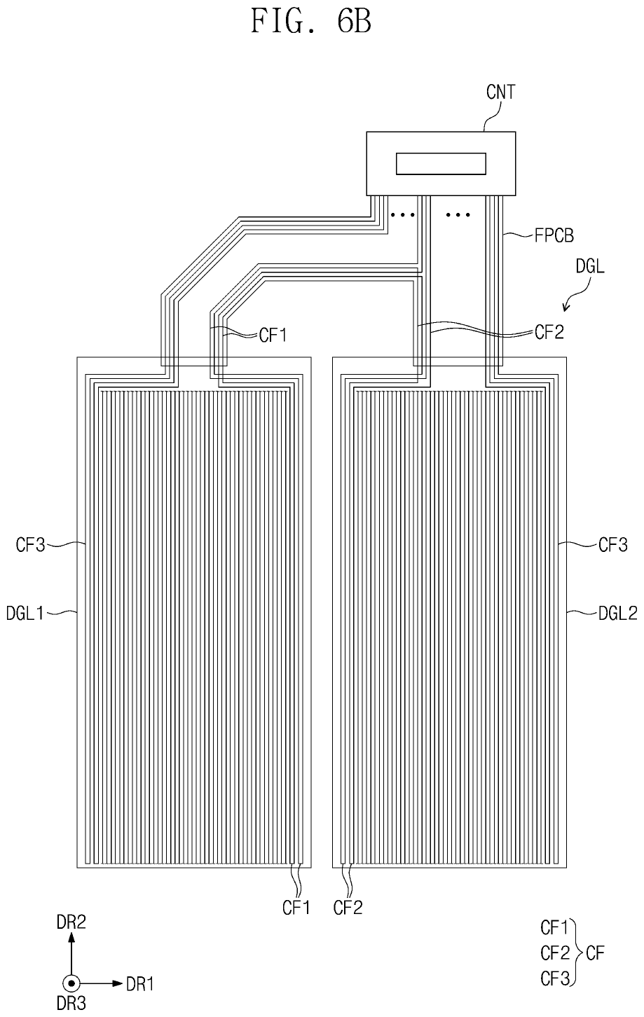

The digitizer module DTM may include a plurality of coils RF, CF (see FIGS. 6A and 6B), a base layer BSL (see FIG. 5), and cover layers CVL1, CVL2 (see FIG. 5). The digitizer module DTM may receive position information indicated by the user on the display surface. The digitizer module DTM may be implemented in an electromagnetic way (or an electromagnetic resonance way). For example, the digitizer module DTM may include a digitizer layer including a plurality of coils. However, the embodiment is not limited thereto, and the digitizer module DTM may be implemented in an active electrostatic way.

In case that the user moves the pen SP (see FIG. 1A) on the display device ED, the pen SP (see FIG. 1A) is driven by an alternating current signal so as to generate an oscillating magnetic field, and the oscillating magnetic field may induce signals to the coils. The position of the pen SP may be detected through the signals induced to the coils. The digitizer module DTM may sense an electromagnetic change generated by an access of the pen SP to find the position of the pen SP. The digitizer module DTM will be described more detail below.

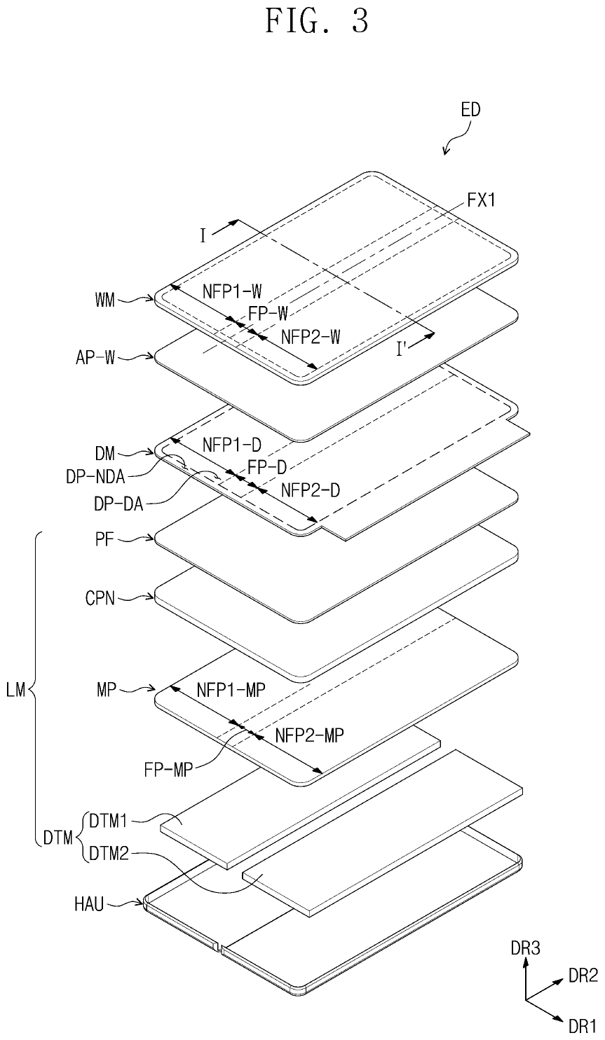

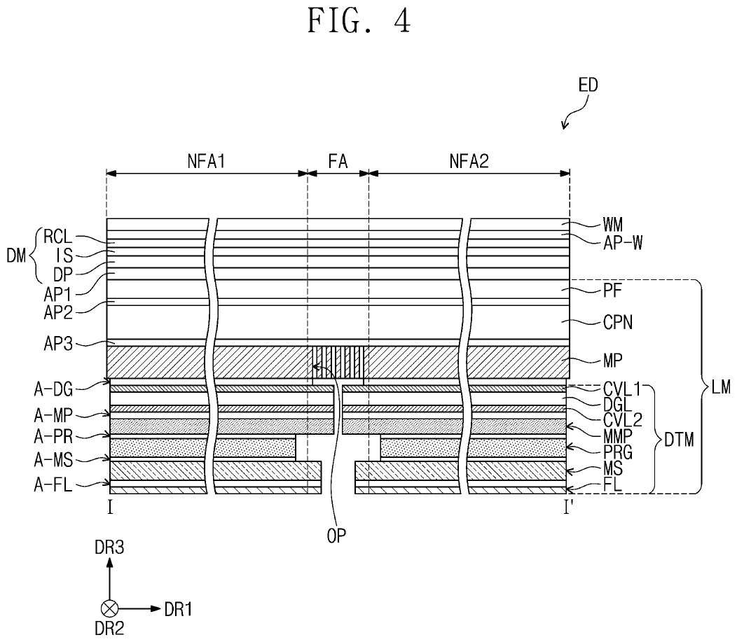

FIG. 3 is an exploded perspective view of a display device according to an embodiment. FIG. 3 is the exploded perspective view of a display device according to an embodiment, and FIG. 4 is a schematic cross-sectional view of the display device according to an embodiment. FIG. 3 shows an example of the exploded perspective view of a display device according to an embodiment shown in FIG. 1A. FIG. 4 is a schematic cross-sectional view showing a portion corresponding to line I-I′ of FIG. 3.

Meanwhile, FIGS. 3 and 4 show a case where the folding axes FX1, FX2 of the display device ED shown in FIG. 1A or the like are parallel to the long sides of the display device ED, but the embodiment is not limited thereto. Descriptions of the display device of an embodiment and the digitizer module according to an embodiment to be described hereinbelow may also be applied to a case where the folding axes FX1, FX2 are parallel to the short sides.

Referring to FIGS. 3 and 4, the display device ED according to an embodiment may include a display module DM, a lower module LM disposed below the display module DM, and a window module WM disposed over the display module DM.

The display device ED according to an embodiment may further include a window adhesive layer AP-W disposed between the display module DM and the window module WM. The window module WM may include a window of glass or a polymer material, and a functional layer or an optical film layer such as a protection film disposed over the window. The window adhesive layer AP-W may be an optically clear adhesive (OCA) film or an optically clear adhesive resin (OCR) layer. The window adhesive layer AP-W may be omitted in an embodiment.

The window module WM may include a folding part FP-W and non-folding parts NFP1-W, NFP2-W. The first non-folding part NFP1-W and the second non-folding part NFP1-W of the window module WM may be spaced apart from each other in the first direction DR1 with the folding part FP-W interposed therebetween. The folding part FP-W is a portion corresponding to the folding area FA (see F1A), and the non-folding parts NFP1-W, NFP2-W may be portions corresponding to the non-folding areas NFA1 and NFA2 (see FIG. 1A).

In an embodiment, the window module WM may include a cover window of a glass material. For example, the window module WM of an embodiment may include reinforced glass, and be foldable so that the first non-folding part NFP1-W and the second non-folding part NFP2-W face each other on the basis of the folding part FP-W.

The lower module LM is disposed below the display module DM and may be referred to as a support member. The display device ED may include a housing HAU accommodating the display module DM and the lower module LM. The housings HAU may be combined to the window module WM. Although not shown, the housing HAU may further include a hinge structure for facilitating folding or bending.

The display module DM may display images, and transmit and receive information about external inputs in response to electrical signals. The display module DM may include a display area DP-DA and a non-display area DP-NDA. The display area DP-DA may be defined as an area onto which the image provided from the display module DP are projected.

The non-display area DP-NDA may be adjacent to the display area DP-DA. For example, the non-display area DP-NDA may surround the display DP-DA. However, this is an example, and the non-display area DP-NDA may be defined with various shapes and is not limited to any one embodiment. According to an embodiment, the display area DP-DA of the display module DM may correspond to at least a portion of the first active area F-AA (see FIG. 1A).

In an embodiment, the display module DM may include the display layer DP. The display layer DP may be an emissive display panel, but is not particularly limited thereto. For example, the display layer DP may be an organic light emitting display panel or an inorganic light emitting display panel. A light emitting layer of the organic light emitting display panel may include an organic light emitting material. A light emission layer of the inorganic light emitting display panel may include quantum dots, quantum rods, and the like within the spirit and the scope of the disclosure.

The display module DM may further include a sensor layer IS. The sensor layer IS may be directly disposed on the display layer DP. The sensor layer IS may include a plurality of sensing electrodes. The sensor layer IS may sense an external input in a mutual cap manner or a self cap manner. The sensor layer IS may also sense an input from an active type input device.

During manufacturing the display layer DP, the sensor layer IS may be directly provided on the display layer DP through continuous processes. However, the embodiment is not limited thereto, and the sensor layer IS may be manufactured as a separate panel from the display layer DP to be adhered to the display layer DP through an adhesive layer (not shown).

The display module DM may further include an optical layer RCL. The optical layer RCL may function to reduce the reflection of external light. For example, the optical layer RCL may include a polarization layer or a color filter layer. However, the embodiment is not limited thereto, and the optical layer RCL may include optical members for improving the display quality of the display device ED.

In an embodiment, the optical layer RCL may be directly disposed on the sensor layer IS. In case that the sensor layer IS is omitted in the display module DM, the optical layer RCL may be directly disposed on the display layer DP. However, the embodiment is not limited thereto, and the optical layer RCL may be disposed on the display layer DP or the sensor layer IS using a separate adhesive member.

The display module DM may include a folding display part FP-D and non-folding display parts NFP1-D, NFP2-D. The folding display part FP-D is a portion corresponding to the folding area FA (see FIG. 1A), and the non-folding display parts NFP1-D, NFP2-D may be portions corresponding to the non-folding areas NFA1, NFA2 (see FIG. 1A).

The folding display part FP-D may correspond to a portion folded or bended along the folding axes FX1, FX2 (see FIG. 1B). The display module DM may include the first non-folding display part NFP1-D and the second non-folding display part NFPD-2, and the first non-folding display part NFP1-D and the second non-folding display part NFPD-2 may be spaced apart from each other in the first direction DR1 with the folding display part FP-D interposed therebetween. The folding display part FP-D may be a portion corresponding to the folding area FA of the display device ED, and the first non-folding display part NFP1-D and the second non-folding display part NFPD-2 may be respective portions corresponding to the first non-folding area NFA1 and the second non-folding area NFA2 of the display device ED.

In the display device ED according to an embodiment, the lower module LM may include the support plate MP and the digitizer module DTM disposed below the support plate MP. The lower module LM may further include a protection layer PF and a buffer layer CPN disposed between the display module DM and the support plate MP.

The digitizer module DTM may include a digitizer layer DGL, a shield layer MMP, and a prepreg layer PRG. The shield layer MMP and the prepreg layer PRG may be disposed below the digitizer layer DGL. The digitizer module DTM will be described more detail below.

The support plate MP may be disposed below the display module DM. The support plate MP may be disposed below the display module DM to support the components disposed over the support place MP, and make it possible for the display device ED to maintain the unfolded or folded state. For a flexible display device including the folding area FA like the display device ED of an embodiment, the support plate MP may support the display module DM even while the shape of the display device ED is modified as in the folding operation.

The support plate MP of an embodiment may include a metal material or a non-metal material. For example, the support plate MP may include at least one of stainless steel, titanium, or a reinforced fiber composite material. The reinforced fiber composite material may include carbon fiber reinforced plastic (CFRP), or glass fiber-reinforced plastic (GFRP).

The support plate MP may include a folding support part FP-MP and non-folding support parts NFP1-MP, NFP2-MP. The first non-folding support part NFP1-MP and the second non-folding support part NFP2-MP of the support plate MP may be spaced apart from each other in the first direction DR1 with the folding support part FP-MP interposed therebetween. The folding support part FP-MP is a portion corresponding to the folding area FA, and the non-folding support parts NFP1-MP, NFP2-MP may be portions corresponding to the non-folding areas NFA1, NFA2.

In correspondence to the folding area FA of the display device ED, a plurality of openings OP may be defined in the support plate MP. The openings OP may be defined in the folding support part FP-MP of the support plate MP. During the folding operation shown in FIGS. 1B to 1D, the stress applied to the support plate MP may be reduced by the openings OP defined corresponding to the folding area FA.

The folding support part FP-MP and the non-folding support parts NFP1-MP, NFP2-MP of the support plate MP may be provided with the same material or a similar material. The folding support part FP-MP and the non-folding support parts NFP1-MP, NFP2-MP may be integral.

Referring to FIGS. 3 and 4, the protection layer PF may be provided between the display module DM and the support plate MP. The protection layer PF may be disposed below the display module DM to protect the rear surface of the display module DM. The protection layer PF may overlap the entirety of the display module DM. The protection layer PF may include a polymer material. For example, the protection layer PF may be a polyimide film or a polyethylene terephthalate film. However, this is an example, and the material of the protection layer PF is not limited thereto.

The display device ED of an embodiment may further include the buffer layer CPN in the lower module LM. The buffer layer CPN may serve as a thickness compensation layer formed to compensate a lower thickness of the display module DM, or a support layer formed to support the display module DM. Unlike the drawing, the buffer layer CPN of an embodiment may be omitted.

In the display device ED of an embodiment, a combination of the components included in the lower module LM may vary according to the size, shape, operation characteristics or the like of the display device ED.

The display device ED of an embodiment may further include one or more adhesive layers AP1, AP2, AP3. For example, the first adhesive layer AP1 may be disposed between the display module DM and the protection layer PF, the second adhesive layer AP2 may be disposed between the protection layer PF and the buffer layer CPN, and the third adhesive layer AP3 may be disposed between the plate MP and the buffer layer CPN. The one or more adhesive layers AP1, AP2, AP3 may be optically clear adhesive (OCA) films or optically clear adhesive resin (OCR) layers. However, the embodiment is not limited thereto, and the transmittance of the one or more adhesive layers AP1, AP2, AP3 may be as low as 80% or smaller.

The display device ED according to an embodiment may include the digitizer module DTM disposed below the display panel MP. A fourth adhesive layer A-DG may be further disposed between the support plate MP and the digitizer module DTM.

The digitizer module DTM according to an embodiment may include a digitizer layer DGL, the shield layer MMP and the prepreg layer PRG disposed in a lower portion of the digitizer layer DGL. The digitizer module DTM may include a metal sheet MS disposed in a lower portion of the digitizer layer DGL. The digitizer module DTM may further include a film layer FL disposed below the metal sheet MS.

In an embodiment shown in FIG. 4, the digitizer module DTM may include a first cover layer CVL1 and a second cover layer CVL2 respectively disposed over and below the digitizer layer DGL. The digitizer module DTM may include at least one adhesive layer A-MP, A-PR, A-MS, A-FL disposed on at least one of the top and bottom of the shield layer MMP, the top and bottom of the prepreg layer PRG, or the top and bottom of the metal sheet MS. The at least one adhesive layer A-MP, A-PR, A-MS, A-FL included in the digitizer module DTM may be a pressure sensitive adhesive layer, a hot melt adhesive layer to which the adhesion is given by heat, or the like within the spirit and the scope of the disclosure. However, the embodiment is not limited thereto, and the at least one adhesive layer A-MP, A-PR, A-MS, A-FL included in the digitizer module DTM may be used without limit, only if the adhesive layer does not influence the sensing characteristics of the digitizer layer DGL.

FIG. 5 is a schematic cross-sectional view of the digitizer module according to an embodiment. FIGS. 6A and 6B are respective schematic plan views of the digitizer layer according to embodiments. FIG. 7A is a schematic perspective view of a prepreg layer according to an embodiment, and FIG. 7B is a schematic cross-sectional view of a prepreg layer according to an embodiment.

Referring to FIG. 5, the digitizer module DTM according to an embodiment may include the digitizer layer DGL, the shield layer MMP disposed below the digitizer layer DGL, and the prepreg layer PRG disposed below the shield layer MMP. The digitizer module DTM in the embodiment shown in FIG. 5 may include a first cover layer CVL1 disposed over the digitizer layer DGL and a second cover layer CVL2 disposed below the digitizer layer DGL. The digitizer module DTM may further include a metal sheet MS disposed below the shield layer MMP.

The display device ED (see FIG. 4) of an embodiment may include at least one folding area FA, and the digitizer module DTM according to an embodiment may include a first digitizer module DTM1 and a second digitizer module DTM2 spaced apart from each other in a portion overlapping the folding area FA. In an embodiment, the first digitizer module DTM1 may be disposed corresponding to the first non-folding area NFA1, and the second digitizer module DTM2 may be disposed corresponding to the second non-folding area NFA2.

Namely, in an embodiment, the first digitizer module DTM1 and the second digitizer module DTM2 may be spaced apart from each other in the area overlapping the folding display parts FP-D (see FIG. 3). The first digitizer module DTM1 may overlap the first non-folding display part NFP1-D, and the second digitizer module DTM2 may overlap the second non-folding area NFP2-D.

The first digitizer module DTM1 may include a first digitizer layer DGL1, a first shield layer MMP1 disposed below the first digitizer layer DGL1, and a first prepreg layer PRG1 disposed below the first shield layer MMP1. The second digitizer module DTM2 may include a second digitizer layer DGL2, a second shield layer MMP2 disposed below the second digitizer layer DGL2, and a second prepreg layer PRG2 disposed below the second shield layer MMP2. Each of the first digitizer module DTM1 and the second digitizer module DTM1 may include the first cover layer CVL1 and the second cover layer CVL2. The first digitizer module DTM1 may further include a first metal sheet MS1, and the second digitizer module DTM2 may further include a second metal sheet MS2.

The digitizer layer DGL may include the base layer BSL, a first coil RF disposed on the top surface of the base layer BSL, and a second coil CF disposed on the bottom surface of the base layer BSL. The base layer BSL may function as a support member on which the first coil RF, the second coil CF or the like are disposed. For example, the base layer BSL may include polyimide.

The first coil RF and the second coil CF each may be a loop coil formed to generate a magnetic field of a preset resonant frequency with the pen SP (see FIG. 1A). The first coil RF and the second coil CF may be patterned on the base layer BSL. The first coil RF and the second coil CF may include copper (Cu).

Each of the first digitizer layer DGL1 and the second digitizer layer DGL2 each may include the base layer BSL, the first coil RF, and the second coil CF.

FIGS. 6A and 6B are schematic plan views each showing the digitizer layer. FIG. 6A is a schematic plan view showing the disposition of the first coils, and FIG. 6B is a schematic plan view showing the disposition of the second coils.

Referring to FIGS. 6A and 6B, the first digitizer layer DGL1 and the second digitizer layer DGL2 may be spaced apart from each other in the first direction DR1. Referring to FIGS. 6A and 6B, the display device ED (see FIG. 3) may include a flexible circuit board FPCB connecting the first digitizer layer DGL1 and the second digitizer layer DGL2, and a connector CNT connected to the flexible circuit board FPCB. The flexible circuit board FPCB may connect to each other the first digitizer layer DGL1 and the second digitizer DGL2. Although not shown, the connector CNT may be connected to a main board. In the main board, an integrated circuit chip formed to drive the digitizer layer DGL may be disposed.

The digitizer layer DGL may include a plurality of first coils RF and a plurality of second coils CF. The first coils RF may be disposed on the second coils CF. In an embodiment, the first coils RF may be defined as X-axis coils extending in the first direction DR1, and the second coils CF may be defined as Y-axis coils extending in the second direction DR2.

Referring to FIG. 6A, the first and second digitizer layers DGL1, DGL2 each may include the plurality of first coils RF. The first coils RF may extend longer in the first direction DR1 from each of the first and second digitizer layers DGL1, DGL2 in a loop shape.

The first coils RF of the first digitizer layer DGL1 may be connected to the first coils RF of the second digitizer layer DGL2 through the flexible circuit board FPCB. By way of example, each of the first coils extend from the connector CNT to the first digitizer layer DGL1 through the flexible circuit board FPCB.

The first coils RF may extend from the first digitizer layer DGL1 in the loop shape, and extend to the second digitizer layer DGL2 through the flexible circuit board FPCB. The first coils RF, which have extended to the second digitizer layer DGL2, may extend at the second digitizer layer DGL2 in a loop shape to be connected to the connector CNT through the flexible circuit board FPCB.

Namely, one of the ends, for example, of the first coils RF may be connected to the connector CNT, each of the first coils may extend to the flexible circuit board FPCB, the first digitizer layer DGL1, the flexible circuit board FPCB, the second digitizer layer DGL2, and to the flexible circuit board FPCB, and the other ends of the first coils may be connected to the connector CNT.

The first coils RF of the first digitizer layer DGL1 and the first coils RF of the second digitizer layer DGL2 may be connected to each other to form the loop shape, and thus X-axis coils of the digitizer layer DGL may be provided.

For example, in FIG. 6A, some or a number of the first coils RF are shown as extending in the loop shape, and the other first coils RF are shown as extending in the first direction DR1 in the first and second digitizer layers DGL1, DGL2 with the left and right portions being omitted. In the first and second digitizer layer DGL1 and DGL2, the first coils RF may extend in the first direction DR1 to be arranged or disposed in the second direction DR2.

Referring to FIG. 6B, the first and second digitizer layers DGL1, DGL2 may include the second coils CF. The second coils CF may extend longer in the second direction DR2 from each of the first and second digitizer layers DGL1, DGL2 in a loop shape.

One side or a side of the first digitizer layer DGL1 and one side or a side of the second digitizer layer DGL2 may face each other. The second coils CF may include 2-1st coils CF1 adjacent to the one side or a side of the first digitizer layer DGL1, 2-2nd coils CF2 adjacent to the one side or a side of the second digitizer layer DGL2, and 2-3rd coils CF3 defined as the remaining second coils CF other than the 2-1st and 2-2nd second oils CF1, CF2.

The 2-1st coils CF1 of the first digitizer layer DGL1 may be connected to the 2-2nd coils CF2 of the second digitizer layer DGL2 through the flexible circuit board FPCB. The 2-1st coils CF1 may extend from the connector CNT to the first digitizer layer DGL1 through the flexible circuit board FPCB. The 2-2nd coils may extend from the connector CNT to the second digitizer layer DGL2 through the flexible circuit board FPCB.

The 2-1st coils CF1 may extend from the first digitizer layer DGL1 in the loop shape, and extend to the flexible circuit board FPCB. The 2-2st coils CF2 may extend from the first digitizer layer DGL2 in a loop shape, and extend to the flexible circuit board FPCB to be connected to the 2-1st digitizer layer CF1.

The 2-1st coils CF1 and the 2-2nd coils CF2 may be substantially integral. Namely, ends of some or a number of the second coils CF (for example, the second coils CF adjacent to the one side or a side of the first digitizer layer DGL1) may be connected to the connector CNT, each of some or a number of the second coils CF may extend to the flexible circuit board FPCB, the first digitizer layer DGL1, the flexible circuit board FPCB, the second digitizer layer DGL2, and to the flexible circuit board FPCB, and the other ends of the some or a number of the second coils may be connected to the connector CNT.

The 2-3rd coils CF3 of the first digitizer layer DGL1 may be connected to the connector CNT to extend to the first digitizer layer DGL1 through the flexible circuit board FPCB, and extend in a loop shape in the first digitizer layer DGL1. The 2-3rd coils CF3 of the second digitizer layer DGL2 may be connected to the connector CNT to extend to the second digitizer layer DGL2 through the flexible circuit board FPCB, and extend to the second digitizer layer DGL2 in a loop shape.

The 2-1st, 2-2nd, and 2-3rd coils CF1, CF2, CF3 extend in the second direction DR2 to provide Y-axis coils of the digitizer layer DGL.

For example, some or a number of the second coils CF are shown as extending in the loop shape, and the other second coils CF are shown as extending in the second direction DR2 in the first and second digitizer layers DGL1, DGL2 with the left and right portions being omitted. In the first and second digitizer layers DGL1 and DGL2, the second coils CF may extend in the second direction DR2 to be arranged or disposed in the first direction DR1.

In an embodiment, the second coils CF may be defined as driving coils, and the first coils RF may be defined as sensing coils. However, the embodiment is not limited thereto and the opposite may also be possible. In case that a current flows through the second coils CF, the lines of magnetic force may be induced between the second coils CF and the first coils RF. The first coils RF may sense the induced electromagnetic force emitted from the pen SP (see FIG. 1A) to output the induced electromagnetic force as sensing signals to one of the terminals of the first coils RF.

Referring to FIG. 5 again, the first digitizer layer DGL1 may overlap the first non-folding area NFA1, and the second digitizer layer DGL2 may overlap the second non-folding area NFA2. The first digitizer layer DGL1 and the second digitizer layer DGL 2 may be spaced apart from each other in the first direction DR1 in the folding area FA. Namely, the first digitizer layer DGL1 and the second digitizer layer DGL2 may respectively overlap the first non-folding display part NFP1-D (scc FIG. 3) and the second non-folding display part NFP2-D (see FIG. 3), and be spaced apart from each other by a first space interval W₁.

In an embodiment, the first cover layer CVL1 may be disposed over the digitizer layer DGL, and the second cover layer CVL2 may be disposed below the digitizer layer DGL. The cover layer CVL1 may cover the first coil RF, and the second cover layer CVL2 may cover the second coil CF. The first cover layer CVL1 may be disposed over the base layer BSL, and the second cover layer CVL2 may be disposed below the second coil BSL.

The first cover layer CVL1 may include a first sensitive adhesive layer AD1 and a first insulation layer IL1, and the second cover layer CVL2 may include a second sensitive adhesive layer AD2 and the second insulation layer IL2. The first sensitive adhesive layer AD1 may cover the first coil RF, and the first insulation layer IL1 may be spaced apart from the base layer BSL with the first sensitive adhesive layer AD1 interposed therebetween. The second sensitive adhesive layer AD2 may cover the second coil CF, and the second insulation layer IL2 may be spaced apart from the base layer BSL with the second sensitive adhesive layer AD2 interposed therebetween.

The first insulation layer IL1 and the second insulation layer IL2 may include polyimide. The first sensitive adhesive layer AD1 may combine the first insulation layer IL1 to the digitizer layer DGL, and the second sensitive adhesive layer AD2 may combine the second insulation layer IL2 to the digitizer layer DGL. The first cover layer CVL1, the digitizer layer DGL, and the second cover layer CVL2 may be combined together with heat provided. For example, the first cover layer CVL1, the digitizer layer DGL, and the second cover layer CVL2 may be combined together through a hot press process. The first sensitive adhesive layer AD1 and the second sensitive adhesive layer AD2 each may be a pressure sensitive adhesive layer, a hot melt adhesive layer to which the adhesion is given by heat, or the like within the spirit and the scope of the disclosure. However, the embodiment is not limited thereto, and an adhesive material formed to adhere the first insulation layer IL1 to the base layer BSL, or the second insulation layer IL2 to the base layer BSL may be used as a material for the sensitive adhesive layers AD1, AD2 without limit.

The digitizer module DTM according to the embodiment shown in FIG. 5 may include the shield layer MMP, the prepreg layer PRG, and the metal sheet MS that are sequentially disposed in a direction spaced apart from the digitizer layer DGL below the digitizer layer DGL. The second cover layer CVL2 may be disposed between the digitizer layer DGL and the shield layer, and the first cover layer CVL1 may be disposed in an upper portion of the digitizer layer DGL. The digitizer module DTM may include adhesive layers A-MP, A-PR, A-MS respectively disposed between the second cover layer CVL2 and the shield layer MMP, between the shield layer MMP and the prepreg layer PRG, and between the prepreg layer PRG and the metal sheet MS. The adhesive layers A-MP, A-PR, A-MS may be pressure sensitive adhesive layers, hot melt adhesive layers to which the adhesion is given by heat, or the like within the spirit and the scope of the disclosure. However, the embodiment is not limited thereto.

The prepreg layer PRG may be disposed below the digitizer layer DGL to function to support the digitizer layer DGL. The prepreg layer PRG may maintain the unfolded state and the folded state of the display device ED (see FIG. 3). For example, the prepreg layer PRG may support the digitizer layer DGL in the unfolded state and the folded state. The prepreg layer PRG may include a first prepreg layer PRG1 corresponding to at least the first non-folding area NFA1 (see FIG. 5) and a second prepreg layer PRG2 corresponding to the second non-folding area NFA2. The first prepreg layer PRG1 and the second prepreg layer PRG2 may be spaced apart from each other in the first direction DR1.

The first prepreg layer PRG1 may overlap at least a portion of the first non-folding display part NFP1-D (see FIG. 3), and the second prepreg layer PRG2 may overlap at least a portion of the second non-folding display part NFP2-D (see FIG. 3). The first prepreg layer PRG1 and the second prepreg layer PRG2 may not overlap the folding display part FP-D (see FIG. 3). The first prepreg layer PRG1 and the second prepreg layer PRG2 may be spaced apart from each other in the first direction DR1 by a second space interval W2.

The first space interval W₁ in the first direction DR1 between the first digitizer layer DGL1 and the second digitizer layer DGL2 may be smaller than the second space interval W2 in the first direction DR1 between the first prepreg layer PRG1 and the second prepreg layer PRG2.

For example, at least portions of the first digitizer layer DGL1 and the second digitizer layer DGL2 may be disposed corresponding to the folding area FA, and the first space interval W₁ may be smaller than the width of the folding area FA in the first direction DR1. The first digitizer layer DGL1 and the second digitizer layer DGL2 are spaced apart from each other in the folding area FA to facilitate the folding operation, and are spaced by the first space interval W₁, which is smaller than the width in the first direction DR1 of the folding area FA, to improve the sensitivity of the digitizer layer DGL even in the folding area FA.

The first prepreg layer PRG1 and the second prepreg layer PRG2 may not correspond to the folding area FA. The second space interval W2 in the first direction DR1 between the first prepreg layer PRG1 and the second prepreg layer PRG2 may be larger than the width in the first direction DR1 of the folding area FA. The first prepreg layer PRG1 is disposed to overlap the first digitizer layer DGL1, and the second prepreg layer PRG2 is disposed to overlap the second digitizer layer DGL2. Accordingly, the digitizer layer DGL may be sufficiently supported by the prepreg layer PRG even in an operation in which the digitizer layer DGL is unfolded or folded, or in a state where the digitizer layer DGL is folded. The first prepreg layer PRG1 and the second prepreg layer PRG2 are disposed to be spaced apart by the second space interval W2 so as not to overlap the folding area FA, and thus the stress applied to the digitizer layer DGL or the like may be reduced during the folding operation.

The thickness t_{PR} of the digitizer PRG may be in a range of about 50 μm to about 60 μm. With the thickness in a range of about 50 μm to about 60 μm, the prepreg layer PRG may maintain favorably the folding characteristics and sufficiently support the digitizer layer DGL.

The prepreg layer PRG may include glass fibers or carbon fibers. The prepreg layer PRG may not include a metal material, but include glass fibers or carbon fibers to exhibit excellent strength characteristics.

FIG. 7A is a schematic perspective view of a prepreg layer according to an embodiment, and FIG. 7B is a schematic cross-sectional view of the prepreg layer according to an embodiment. FIG. 7B may be a schematic cross-sectional view of a portion corresponding to line II-II′ in FIG. 7A.

Referring to FIGS. 7A and 7B, the prepreg layer PRG may include the first prepreg layer PRG1 and the second prepreg layer PRG2 spaced apart from each other in the first direction DR1, and each include fibers GF. The first prepreg layer PRG1 and the second prepreg layer PRG2 each may include fibers GF and a matrix part RSM formed to fill between the fibers GF or cover the fibers GF. The prepreg layer PRG may be a composite material layer including the matrix part RSM and the fibers GF.

The matrix part RSM may be manufactured from a polymer resin. The matrix part RSM may be manufactured from the polymer resin including at least one of a urethane-based resin, an epoxy-based rein, a polyester-based resin, a polyether-based resin, an acrylate-based resin, a polyimide-based resin, or an acrylonitrile-butadiene-styrene (ABS) resin.

The fibers GF may extend in the first direction DR1 or the second direction DR2. In an embodiment, the fibers GF extending in the first direction DR1 and the fibers GF extending in the second direction DR2 may be weaved to intersect each other. FIGS. 7A and 7B show an embodiment in which the fibers GF are woven, but the array and woven shape of the fibers GF are not limited thereto.

The prepreg layer PRG may be provided in a way that the arrayed and woven fibers GF are immersed in the polymer resin, and fixed through a thermal curing process or the like within the spirit and the scope of the disclosure. The prepreg layer PRG may include high strength fibers GF such as glass fibers or carbon fibers to exhibit excellent rigidity. The prepreg layer PRG may include the woven glass fibers, the woven carbon fibers, or the like to exhibit excellent rigidity and also lightweight characteristics in comparison to a metal material, etc.

Referring to FIG. 5, the digitizer module DTM according to an embodiment may include the shield layer MMP. The shield layer MMP in an embodiment shown in FIG. 5 may be disposed between the digitizer layer DGL and the prepreg layer PRG.

The shield layer MMP may be disposed below the digitizer layer DGL to attenuate electromagnetic noises or the like influencing the digitizer layer DGL, and improve the sensing performance of the digitizer layer DGL. For example the shield layer MMP may block electromagnetic waves generated from the electronic modules EM1, EM2 or the like from influencing the digitizer layer DGL as noises.

The shield layer MMP may include a first shield layer MMP1 corresponding to the first non-folding area NFA1 and a second shield layer MMP2 corresponding to the second non-folding area NFA2. The first shield layer MMP1 and the second shield layer MMP2 may be spaced apart from each other in a portion corresponding to the folding area FA in the first direction DR1.

The shield layer MMP may include magnetic metal powder. The first shield layer MMP1 and the second shield layer MMP2 may include the same magnetic metal powder.

The digitizer module DTM according to an embodiment may further include the metal sheet MS. In the embodiment shown in FIG. 5, the metal sheet MS may be disposed below the prepreg layer PRG. In an embodiment, the metal sheet MS may function as a heat dissipation layer. The metal sheet MS may include a metal material with a high thermal conductivity to exhibit excellent heat dissipation characteristics.

The metal sheet MS may include copper(Cu). For example, the metal sheet MS may be copper sheet. The metal sheet MS may have a smaller thickness than the prepreg layer PRG. The metal sheet MS having relatively small thickness may have excellent folding characteristics without increasing the thickness of the display device.

The metal sheet MS may include a first metal sheet MS1 corresponding to the first non-folding area NFA1 and a second metal sheet MS2 corresponding to the second non-folding area NFA2. The first metal sheet MS1 and the second metal sheet MS2 may be spaced apart from each other in the first direction DR1 in a portion corresponding to the folding area FA. The digitizer module DTM in an embodiment may include the first metal sheet MS1 and the second metal sheet MS2 spaced apart in the folding area FA to exhibit good folding operation characteristics.

The cover layers CVL1, CVL2, the digitizer layer DGL, the shield layer MMP, the prepreg layer PRG, and the metal sheet MS included in the digitizer module DTM according to the embodiment shown in FIG. 5 may be assembled into a single component to be provided to the display device ED (see FIG. 3). Namely, the functional layers of the cover layers CVL1, CVL2, the digitizer layer DGL, the shield layer MMP, the prepreg layer PRG, metal sheet MS and the like are provided as respective separate components, are not sequentially combined in a separate step of a lamination or assembly process, and may be combined with the support plate MP (see FIG. 3) in the type of the digitizer module DTM in which the functional layers are assembled into a single component.

The functional layers of the cover layers CVL1, CVL2, the digitizer layer DGL, the shield layer MMP, the prepreg layer PRG, the metal sheet MS, and the like, and the adhesive layers A-MP, A-PR, A-MS, A-FL between the functional layers are laminated and combined to each other through the hot press process to provide the digitizer module DTM. For example, the digitizer module DTM in the embodiment shown in FIG. 5 may be provided in a state where the first cover layer CVL1, the digitizer layer DGL, the second cover layer CVL2, the adhesive layer A-MP, the shield layer MMP, the adhesive layer A-PR, the prepreg layer PRG, the adhesive layer A-MS, and the metal sheet MS are sequentially laminated downward and combined to each other through a single hot press process. Unlike this, the first cover layer CVL1 and the digitizer layer DGL in an embodiment are separately combined in the hot press process, and in a state where the laminate structure in which the first cover layer CVL1 and the digitizer layer DGL is combined, the second cover layer CVL2, the adhesive layer A-MP, the shield layer MMP, the adhesive layer A-PR, the prepreg layer PRG, the adhesive layer A-MS, and the metal sheet MS are laminated and combined to each other through another single hot press process to finally provide the digitizer module DTM as one member.

In this way, the digitizer module DTM of the embodiment may be manufactured through a minimum hot press process without an additional separate lamination or assembly process, thereby exhibiting excellent surface integrity. In other words, the digitizer module DTM of the embodiment may be manufactured through the minimum hot press process to exhibit excellent surface integrity characteristics by allowing the flexural properties of the functional layers included in the digitizer module DTM to be minimally reflected and displayed on the surface.

The digitizer module DTM of the embodiment may be manufactured to one member through the minimum hot press process without a separate lamination or assembly process, thereby simplifying display device processes.

The digitizer module DTM of an embodiment may include the prepreg layer PRG, which has excellent rigidity and relatively lightweight characteristics, to be disposed in a lower portion of the digitizer layer DGL, thereby maintaining excellent rigidity characteristics and reducing the weight of the display device.

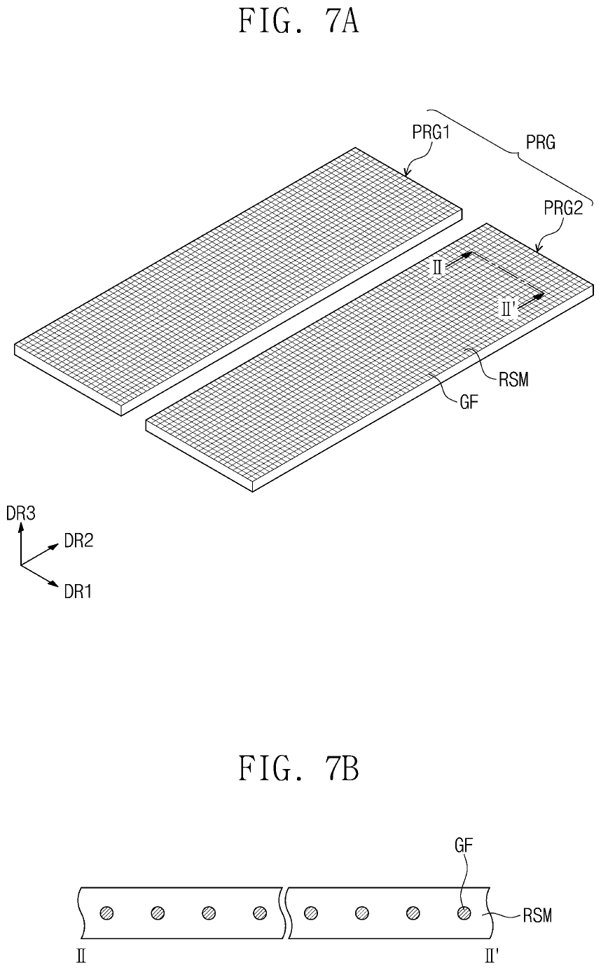

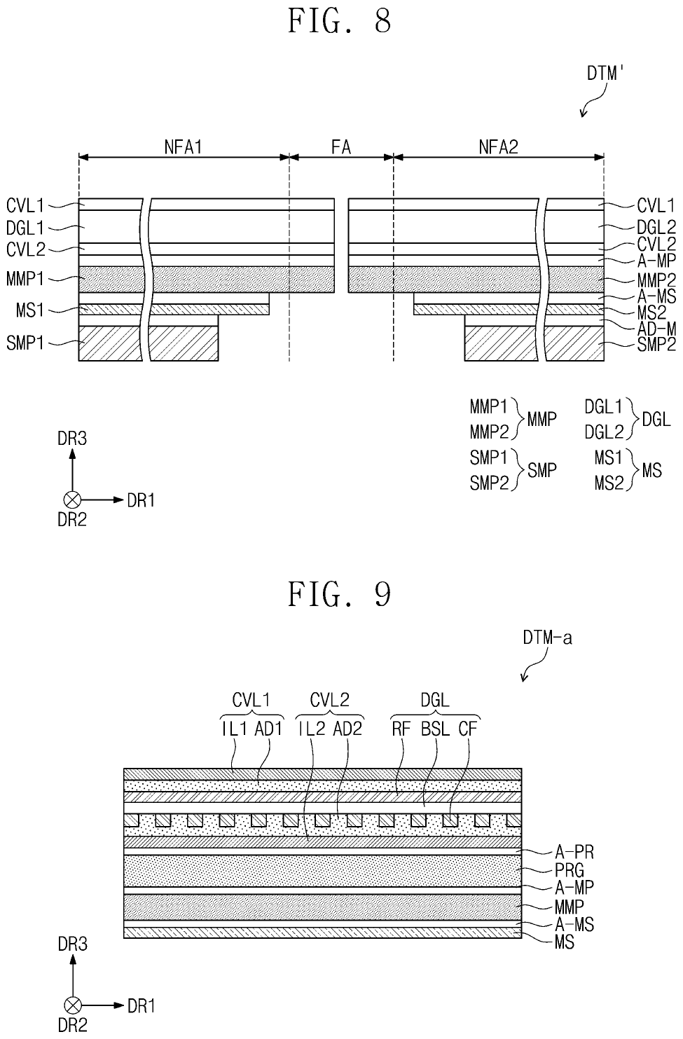

FIG. 8 is a schematic cross-sectional view of a typical digitizer module. The typical digitizer module DTM′ shown in FIG. 8 is different from the digitizer module DTM of the embodiment shown in FIG. 5 or the like in having a metal support layer SMP other than the prepreg layer PRG. The metal support layer SMP may also include first and second metal support layers, SMP1 and SMP2. The typical digitizer module DTM′ may include the digitizer layer DGL, the shield layer MMP, the metal sheet MS, and the metal support layer SMP. The metal support layer SMP may be disposed in the bottom of the digitizer module DTM′, and include a metal material such as SUS. The metal support layer SMP may be combined to the laminate structure of the digitizer layer DGL, the shield layer MMP, and the metal sheet MS by using an interlayer bonding layer AD-M.

For the typical digitizer module DTM′, the laminate structure of the cover layers CVL1, CVL2, the digitizer layer DGL, the adhesive layer A-MP, the shield layer MMP, the adhesive layer A-MS, and the metal sheet MS may be combined, and, through a separate lamination process, a laminate structure of the cover layers CVL1, CVL2, the digitizer layer DGL, the adhesive layer A-MP, the shield layer MMP, the adhesive layer A-MS, and the metal sheet MS is combined to the metal support layer SMP by using the interlayer bonding layer AD-M.

The laminate structure including the digitizer layer DGL, and the metal support layer SMP are assembled using rollers, and, in the lamination process, the surface definition of the digitizer layer DGL may be degraded. Namely, for the typical digitizer module DTM′, a separate process in which the metal support layer SMP is additionally laminated is further performed, and thus the surface roughness of the digitizer module DTM′ is more severe than before the lamination process of the metal support layer SMP, thereby the surface integrity is degraded.

The typical digitizer module DTM′ may include the metal support layer SMP such as SUS or the like to increase the entire weight of the display device, and the cost also increases due to the necessity of SUS surface treatment or the like within the spirit and the scope of the disclosure.

In contrast, the digitizer module of the embodiment is manufactured through the minimum hot press process without the separate lamination or assembly process to exhibit excellent surface integrity characteristics, and may include the prepreg layer without a metal material to maintain excellent strength characteristics and the lightweight effect. The digitizer module of the embodiment may include the prepreg layer including a polymer resin, and glass or carbon fibers. Accordingly, in comparison to adopting the metal support layer of SUS or the like, the digitizer module of the embodiment may maintain the rigidity of the same level or higher, thereby the display device maintains excellent rigidity. The entire weight of the display device may also be reduced and the display device manufacturing cost may be saved too.

The following Table 1 shows the comparison between the typical digitizer module and the digitizer module of the embodiment. In Table 1, a comparative example corresponds to the structure of the typical digitizer module shown in FIG. 8, and an example corresponds to the structure of the digitizer module of the embodiment shown in FIG. 5. In the comparative example of Table 1, before adhesion of the metal support layer corresponds to before adhesion of an SUS substrate, and after adhesion of the metal support layer corresponds to after lamination of the SUS substrate to the digitizer layer or the like within the spirit and the scope of the disclosure.

In Table 1, the surface integrity (Kc) is measured by means of Optimap™, and as smaller a Kc value, the better the surface integrity. The modulus corresponds to a value measured in a 3-axis flexural modulus evaluation method.

TABLE 1

| | | Comparative example | |
|---|---|---|---|
| | | Before adhesion | After adhesion |
| | | of metal | of metal |
| Item | Example | support layer | support layer |
| Surface integrity (Kc) | 2.2~2.4 | 2.4~2.7 | 3.6~4.2 |
| Modulus (GPa) | 15.4 | — | 13.6 |

Referring to Table 1, from the comparative example, it may be understood that the surface integrity of the digitizer module is degraded after adhesion of the metal support layer. In contrast, it may be confirmed that the surface integrity of the example digitizer module exhibits excellent characteristics. For the modulus value, it may also be understood that the example is more excellent than the comparative example, and thus the digitizer module including the prepreg layer other than the metal support layer exhibits more excellent rigidity.

Accordingly, with reference to at least FIGS. 1A, 1B, 1C, and 1D, it may be appreciated that the digitizer module including the prepreg layer with the glass fibers or carbon fibers, other than the typical metal support layer, exhibits more excellent rigidity and more excellent surface integrity, too.

FIGS. 9 to 11 are schematic cross-sectional views of a digitizer module according to embodiments. In the description of the digitizer module according to the embodiments with reference to FIGS. 9 to 11, the details described with reference to FIGS. 1 to 7B will not be repeated again, and differences from the above-described embodiments will be described. FIGS. 9 to 11 each show the digitizer module regardless of the folding area and the non-folding area, but the configuration of each of the digitizer modules shown in FIGS. 9 to 11 may be divided into first and second digitizer modules including a spaced portion in the folding area as in the digitized module of FIG. 5. The digitizer module according to the embodiments shown in FIGS. 9 to 11 may be included in the lower module LM (see FIG. 3) of the display device ED (see FIG. 3) according to the embodiments described with reference to FIGS. 1A to 4.

The digitizer module DTM-a according to the embodiment shown in FIG. 9 may include the digitizer layer DGL, and the prepreg layer PRG and shield layer MMP below the digitizer layer DGL. The digitizer module DTM-a according to the embodiment may include the digitizer layer DGL including the base layer BSL, the first coil RF disposed on the top surface of the base layer BSL, and the second coil disposed on the bottom surface of the base layer BSL, the first cover layer CVL1 over the digitizer layer DGL, and the second cover layer CVL2 below the digitizer layer DGL. The first cover layer CVL1 and the second cover layer CVL2 each may include the sensitive adhesive layers AD1, AD2, and the insulation layers IL1, IL2.

The digitizer module DTM-a of an embodiment may include the second cover layer CVL2, the prepreg layer PRG, the shield layer MMP, and the metal sheet MS that are sequentially disposed in that order below the digitizer layer DGL. The digitizer module DTM-a of the embodiment does not include a separate metal support layer below the digitizer layer DGL except for the metal sheet MS.

The digitizer module DTM-a according to an embodiment may include the first cover layer CVL1, the digitizer layer DGL, the second cover layer CVL2, the adhesive layer A-PR, the prepreg layer PRG, the adhesive layer A-MP, the shield layer MMP, the adhesive layer A-MS, and the metal sheet MS that are sequentially disposed downward, and be provided below the support plate MP (see FIG. 3) in one member type provided through a hot press process without an additional lamination or assembly process.

The digitizer module DTM-a according to the embodiment may include the prepreg layer other than the metal support layer, thereby maintaining the rigidity similar to adopting the metal support layer, and having more excellent surface integrity and lightweight characteristics in comparison to adopting the metal support layer.

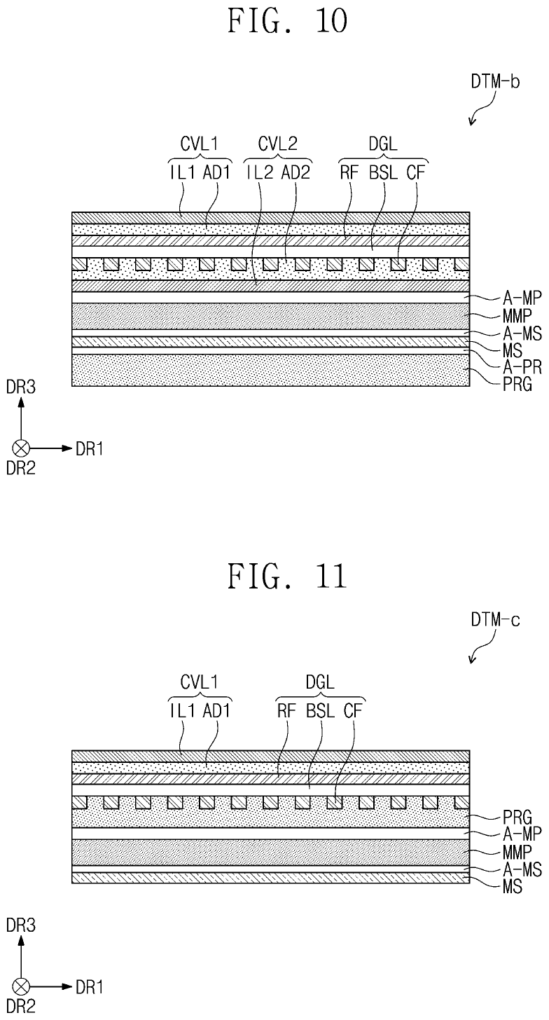

The digitizer module DTM-b according to an embodiment shown in FIG. 10 is different from that DTM-a according to the embodiment shown in FIG. 9 in the position of the prepreg layer PRG. In the embodiment, the prepreg layer PRG may be disposed below the metal sheet MS. In the digitizer module DTM-b of the embodiment, the shield layer MMP, the metal sheet MS, and the prepreg layer PRG may be sequentially disposed below the digitizer layer DGL.

The digitizer module DTM-b of the embodiment may include the first cover layer CVL1, the digitizer layer DGL, the second cover layer CVL2, the adhesive layer A-MP, the shield layer MMP, the adhesive layer A-MS, the metal sheet MS, the adhesive layer A-PR, and the prepreg layer PRG that are disposed downward, and the digitizer module DTM-b may be provided below the support plate MP (see FIG. 3) in one member type provided through the hot press process without a separate lamination or assembly process.

The digitizer module DTM-b according to an embodiment may include the prepreg layer PRG other than the metal support layer, thereby maintaining the rigidity similar to adopting the metal support layer, and having more excellent surface integrity and lightweight characteristics in comparison to adopting the metal support layer.

The digitizer module DTM-c according to an embodiment shown in FIG. 11 is different from the digitizer modules DTM, DTM-a, DTM-b shown in FIGS. 5, 9, and 10 in omitting the second cover layer CVL2 (see FIG. 10).

The digitizer module DTM-c according to the embodiment may include the digitizer layer DGL, the prepreg layer PRG disposed below the digitizer layer DGL, and the shield layer MMP and metal sheet MS disposed below the prepreg layer PRG. The digitizer module DTM-c may include the first cover layer CVL1, the digitizer layer DGL, the prepreg layer RG, the adhesive layer A-MP, the shield layer MMP, the adhesive layer A-MS, and the metal sheet MS that are sequentially laminated downward.

The digitizer layer DGL may include the base layer BSL, the first coil RF disposed on the top surface of the base layer BSL, and the second coil CF disposed on the bottom side of the base layer BSL. The first cover layer CVL1 may cover the first coil CVL1, and the prepreg layer PRG may cover the second coil CF.

The prepreg layer PRG may be directly disposed below the second coil CF to protect the second coil CF, and support the digitizer layer DGL. The prepreg layer PRG may function as a cover layer covering the second coil CF, and as a support layer supporting the digitizer layer DGL in an unfolded state and folded state, and during a folding operation.

The digitizer module DTM-c of the embodiment may include the first cover layer CVL1, the digitizer layer DGL, the prepreg layer PRG, the adhesive layer A-MP, the shield layer MMP, the adhesive layer A-MS, the metal sheet MS that are sequentially disposed downward, and may be provided below the support plate MP (see FIG. 3) in one member type provided through a hot press process without a separate lamination or assembly process.

The digitizer module DTM-a according to the embodiment may include the prepreg layer PRG other than the metal support layer, thereby maintaining the rigidity similar to adopting the metal support layer, and having more excellent surface integrity and lightweight characteristics in comparison to adopting the metal support layer.

The digitizer module according to the embodiment may include the prepreg layer other than the metal layer to exhibit the lightweight characteristics and excellent surface quality, and the display device of the embodiment include such a digitizer module of the embodiment may exhibit a simplified lamination structure of a lower module, and the lightweight characteristics. The display device of the embodiment may exhibit excellent rigidity characteristics that the shape of the display device is favorably maintained even in an unfolded state and folded state.

The display device of the embodiment may include the digitizer module that may include the prepreg layer other than the metal support layer to maintain the excellent rigidity characteristics and exhibit the excellent surface quality. In case that including the prepreg layer, the weight of the display device of the embodiment is reduced compared to adopting the metal support layer.

The display device of the embodiment may include at least one folding area, and first and second digitizer modules spaced apart from each other in a portion corresponding to the folding area, and the first and second digitizer modules each include the prepreg layer below the digitizer layer, thereby exhibiting the excellent folding characteristics, the excellent rigidity and surface integrity characteristics. The display device of the embodiment may include, other than the metal support layer, the prepreg layer integral with the other functional layers of the digitizer module in the hot press process to exhibit the excellent folding characteristics and rigidity, and the weight reduction effect.

The display device according to the embodiments may include the prepreg layer disposed in a lower portion of the digitizer layer and including glass fibers or carbon fibers, thereby maintaining excellent rigidity and support characteristics, and exhibiting lightweight characteristics.

While this disclosure has been described with reference to embodiments thereof, it will be clear to those of ordinary skill in the art to which the disclosure pertains that various changes and modifications may be made to the described embodiments without departing from the spirit and technical area of the disclosure as defined in the appended claims and their equivalents.

Thus, the scope of the disclosure shall not be restricted or limited by the foregoing description, but should be determined by the broadest permissible interpretation of the following claims.

What is claimed is:

1. A display device comprising:
a display module comprising:
a folding display part;
a first non-folding display part; and
a second non-folding display part with the folding display part disposed between the first non-folding display part and the second non-folding display part;
a support plate disposed below the display module, and comprising a plurality of openings that overlap the folding display part; and
a digitizer module comprising:
a first digitizer module overlapping the first non-folding display part; and
a second digitizer module overlapping the second non-folding display part, the first digitizer module and the second digitizer module being disposed below the support plate and spaced apart from each other in an area overlapping the folding display part, wherein the digitizer module comprises:
a digitizer layer comprising:
a base layer;
a first coil disposed on a top surface of the base layer; and
a second coil disposed on a bottom surface of the base layer;
a shield layer disposed below the digitizer layer, and comprising a magnetic metal powder; and
a prepreg layer disposed below the digitizer layer and over or below the shield layer.

2. The display device of claim 1, wherein the digitizer module further comprises:
a first cover layer covering the first coil and disposed over the base layer; and
a second cover layer covering the second coil and disposed below the base layer.

3. The display device of claim 2, wherein
the shield layer is disposed below the second cover layer, and
the prepreg layer is disposed below the shield layer.

4. The display device of claim 2, wherein
the prepreg layer is disposed below the second cover layer, and
the shield layer is disposed below the prepreg layer.

5. The display device of claim 2, wherein
the digitizer module further comprises a metal sheet,
the shield layer is disposed below the second cover layer, and the prepreg layer is disposed below the shield layer, and
the metal sheet is disposed between the shield layer and the prepreg layer.

6. The display device of claim 1, wherein the digitizer module further comprises:
a metal sheet disposed below the digitizer layer; and
adhesive layers disposed on at least one of a top and bottom of the shield layer, a top and bottom of the prepreg layer, and a top and bottom of the metal sheet.

7. The display device of claim 6, wherein the metal sheet comprises copper.

8. The display device of claim 1, wherein
the digitizer module further comprises a first cover layer covering the first coil and disposed over the base layer; and
the prepreg layer covers the second coil and is disposed below the base layer, and the shield layer is disposed below the prepreg layer.

9. The display device of claim 2, wherein
the digitizer layer comprises a first digitizer layer comprised in the first digitizer module, and a second digitizer layer comprised in the second digitizer module,
the prepreg layer comprises a first prepreg layer comprised in the first digitizer module, and a second prepreg module comprised in the second digitizer module, and
a first space interval between the first digitizer layer and the second digitizer layer in the first direction is less than a second space interval between the first prepreg layer and the second prepreg layer in the first direction.

10. The display device of claim 9, wherein the first prepreg layer and the second prepreg layer do not overlap the folding display part.

11. The display device of claim 9, wherein at least a portion of the first digitizer layer and at least a portion of the second digitizer layer each overlap the folding display part.

12. The display device of claim 1, wherein the prepreg layer comprises glass fibers or carbon fibers.

13. The display device of claim 1, wherein a thickness of the prepreg layer is in a range of about 50 μm to about 60 μm.

14. A display device comprising:
a display module;
a support plate disposed below the display module; and
a digitizer module disposed below the support plate,
wherein the digitizer module further comprises:
a digitizer layer comprising a base layer;
a first coil disposed on a top surface of the base layer; and
a second coil disposed on a bottom surface of the base layer;
a shield layer disposed below the digitizer layer, and comprising a magnetic metal powder; and
a prepreg layer disposed, below the digitizer layer, over and below the shield layer, and comprising glass fibers or carbon fibers.

15. The display device of claim 14, wherein the digitizer module further comprises:
a first cover layer covering the first coil and disposed over the base layer; and
a second cover layer covering the second coil and disposed in a lower portion of the base layer.

16. The display device of claim 15, wherein the first cover layer and the second cover layer each comprise:
a sensing adhesive layer covering the first coil or the second coil; and
an insulation layer spaced apart from the base layer with the sensing adhesive layer disposed between the insulation layer and the base layer.

17. The display device of claim 15, wherein
the shield layer is disposed below the second cover layer, and
the prepreg layer is disposed below the shield layer.

18. The display device of claim 15, wherein
the prepreg layer is disposed below the second cover layer, and
the shield layer is disposed below the prepreg layer.

19. The display device of claim 15, wherein
the digitizer module further comprises a metal sheet,
the shield layer is disposed below the second cover layer,
the prepreg layer is disposed below the shield layer, and
the metal sheet is disposed between the shield layer and the prepreg layer.

20. The display device of claim 14, wherein
the digitizer module further comprises a first cover layer covering the first coil and disposed over the base layer, and
the prepreg layer covers the second coil and is disposed below the base layer, and the shield layer is disposed below the prepreg layer.
